(19) United States
(12) Patent Application Publication
(10) Pub. No.: US 2006/0178847 A1
(43) Pub. Date: Aug. 10, 2006

(54) Apparatus and method for wireless real time measurement and control of soil and turf conditions

(76) Inventors: John E. Glancy, Encinitas, CA (US); David McIntosh, Palm City, FL (US); Walter N. Norley, Juno Beach, FL (US)

Correspondence Address: BOND, SCHOENECK & KING, PLLC, ONE LINCOLN CENTER, SYRACUSE, NY, 13202-1355, US

(21) Appl. No.: 11/350,328

(22) Filed: Feb. 8, 2006

Related U.S. Application Data
(60) Provisional application No. 60/651,768, filed on Feb. 9, 2005.

(51) Int. Cl. G01R 21/00

(52) U.S. Cl. 702/62

(57) ABSTRACT

An apparatus and method are provided for monitoring subsurface soil conditions in real time and communicating data about the subsurface soil conditions to a monitor that analyzes the data to provide warnings to the system operator and to automatically initiate one or more soil treatment processes. The apparatus includes nodes with soil condition sensors and radio transceivers. The nodes are communicatively connected by a network that includes at least one transceiver. The nodes optionally include means for controlling turf treatment devices in response to commands from the computer.

This application claims priority to U.S. Provisional Patent Application No. 60/651,768, filed Feb. 9, 2005.

### FIELD OF THE INVENTION

The present invention relates to an apparatus and method that uses subsurface sensors, a radio-linked network, and a computer for wireless, real-time monitoring, historical tracking and predictive modeling of subsurface soil conditions. The present invention also provides for automatic control of soil treatment equipment in response to data obtained by the sensors.

### BACKGROUND OF INVENTION

Current turf management techniques use mainly local weather station information and soil appearance and feel to decide how to treat turf using irrigation, aeration, fumigation, fertilization, and other turf treatments. There are hand held instruments with probes that can be inserted in the soil to measure turf health but these are not practical for real time monitoring. There are also applications of buried-in-ground sensors that measure turf health but these use underground wire to provide power and communications links to the above ground user and this makes wide spread use of underground sensors impractical and expensive. The method of this patent provides a way to locate an inexpensive sensor underground in the root zone of the turf without trenching or running cable. Thus, sensors can be located throughout the turf area and the superintendent can acquire data on root zone health in real-time and this allows him to better treat the turf and to minimize treatment expense and also minimize any impacts on the environment from turf treatment.

Current sensors that can be buried underground for measuring turf health include their own individual electronic systems for signal processing and in situ calibration and processing so that measurements can be relatively independent of soil type. The present invention eliminates the need for these separate electronic systems by allowing these functions alternatively to be performed by software resident in the manager's computer or in the above ground transceiver, then sending necessary calibration signals to the sensor via the communication network.

Current underground turf measurement sensors create a difficulty in properly locating the probes in the soil because the required trenching disturbs the soil. This trenching also requires disturbance of a large amount of the surface during the digging, cutting and backfill. The method of this patent provides a large benefit because a core of turf and soil can be easily removed using a standard cup hole cutter, the sensor node dropped into the hole, and the core replaced using the tool. This is a process that takes minutes and is currently done thousands of times a day on golf courses.

### SUMMARY OF THE INVENTION

The present invention provides a plurality of sensors connected to a radio to create a sensor node, which is buried in the root zone of turf on a golf course or other location. Data on soil conditions (especially soil conditions related to turf health parameters) is wirelessly transmitted in real-time from the node to a transceiver that is connected by a wireless or other network to a computer. The electronics for the sensor and the radio are integrated so the node is small enough to be placed in the root zone using a hole-cutting tool that is typically used to form a cup on a golf course green. Each node has one or more sensors with probes that measure a soil conditions. Sensor probes from a single node can be located at different soil depths. The sensors can be easily calibrated in place by sending calibration signals via the wireless radio link. Each node includes a power management algorithm so that the batteries that power the node will last a long time. Each node can be buried sufficiently deep to avoid damage from turf maintenance equipment and still be able to send signals through the ground to a transceiver above the surface. Because nodes do not require cabling for communications or power supply, it is possible to position nodes rapidly anywhere in the turf without need to trench and lay cable for power and communications. More than one node can communicate with each above ground transceiver. Nodes are also capable of receiving commands and controlling a variety of devices in response to such commands. The computer collects data from each node to provide comprehensive information about the subsoil conditions. The computer includes an algorithm that identifies possible undesired turf conditions based on observed subsurface conditions and also can automatically initiate soil treatment processes in response to observed subsoil conditions, according to parameters established by the operator.

### BRIEF DESCRIPTION OF THE DRAWINGS

The present invention will be more fully understood and appreciated by reading the following Detailed Description in conjunction with the accompanying drawings, in which:

FIG. 1 is a partial sectional perspective view of a sensor node according to the present invention;

FIG. 2 is a schematic view of sensors 18, nodes and a transceiver according to an embodiment of the present invention;

FIG. 3 is a schematic view of transceivers and a computer as installed in a golf course environment, according to an embodiment of the present invention; and

FIG. 4 is a schematic view of the communications interconnection of an embodiment of the invention.

### DESCRIPTION OF THE INVENTION

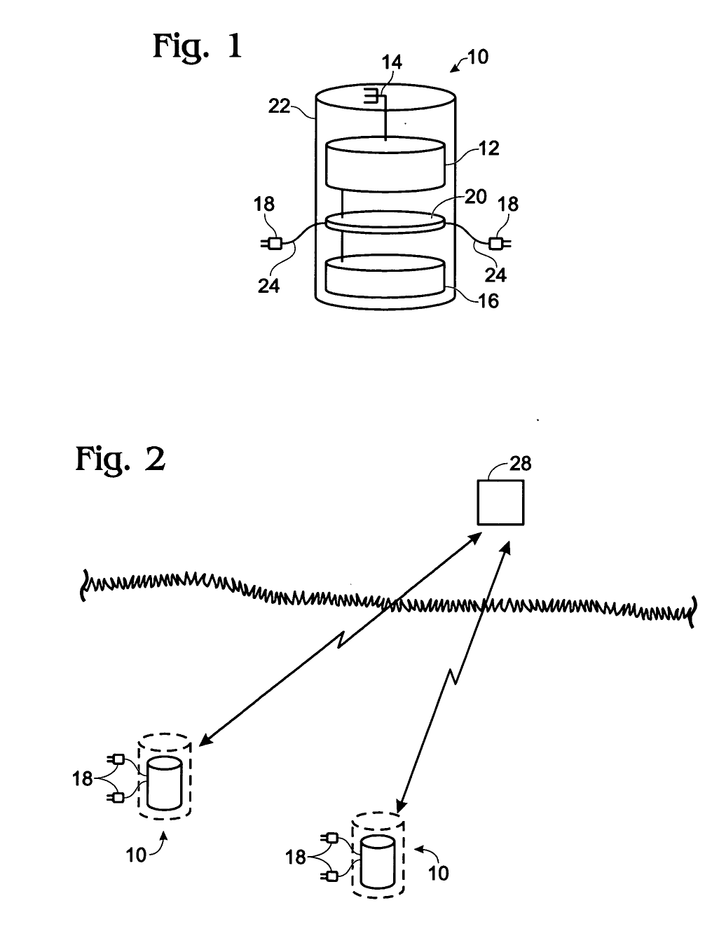

Referring now to the drawings, wherein like reference numerals refer to like parts throughout, there is seen in FIG. 1 a sensor node 10 according to the present invention, which comprises a radio 12, an antenna 14, a battery 16 (or other power supply), a number of sensors 18, and an electronic circuit board 20, all located in a node package 22. The node package 22 is slightly less than the diameter of a golf cup hole and less than 4 inches high. Preferably, the node package 22 consists of ABS plastic water pipe that has been sealed at each end with a standard pipe plug, but other packages 22 are also acceptable and will be known to those skilled in the art. Heavy duty waterproof wires 24 extend from the package 22 and are connected to sensors 18 that preferably include soil probes that extend radially into the soil at different depths so the probe is properly surrounded by soil and a good measurement is accomplished. The wires 24 protrude through one or more holes in the package 22, which are sealed using an “O” ring or silicon sealant. One or more sensors 18 are connected to the protruding wires 24, for sensing soil conditions. The connections between the sensors 18 and the wires 24 preferably are made using waterproof seals such as shrink wrap.

Preferably, the node 10 is buried below the depth of plugging/aeration holes and in the region of the turf root zone (4-8″). The depth of the sensors 18 can be selected by the course superintendent or other user based on measurement requirements for each installation. Preferably, sensors 18 are sufficiently deep that they are not damaged by turf management activity such as plug aeration.

Nodes 10 according to the present invention can be used with a wide variety of sensors 18. Sensors 18 known to be useful for turf management include moisture sensors 18, temperature sensors 18 and salinity sensors 18, but the scope of this invention is not limited by those examples. According to the present invention, soil temperature can be measured by sensors 18 that include thermistors and/or thermocouples. Soil moisture can be measured by sensors 18 that include gypsum or granular matrix blocks and time domain reflectometry probes. Soil salinity can be measured using sensors 18 that include conductivity and time domain reflectometry probes. The present invention, however, is intended to encompass any type of sensor 18 used to measure subsurface soil conditions. In addition, while the invention is intended to comprise subsurface nodes, it is also possible to install one or more nodes above ground to sense ambient atmospheric conditions.

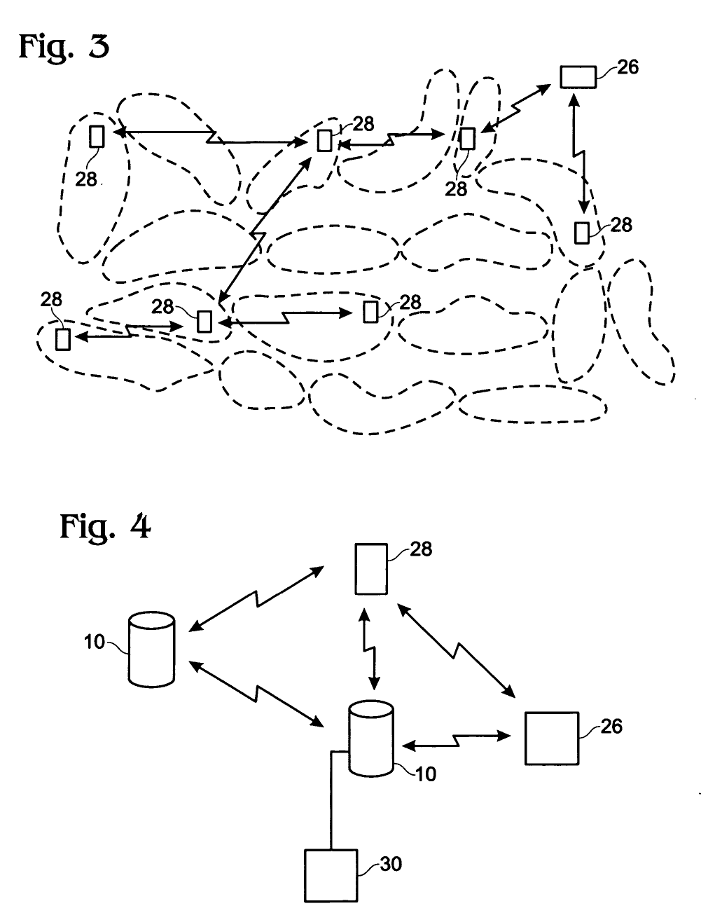

The data from the sensors 18 is not processed at the node 10, but is processed when it is received at the superintendent's computer 26 (FIGS. 3, 4). In this way, sensors 18 can be made less expensively, but the raw data continues to be processed to provide useful information. The above ground transceiver 28 has temporary data storage, with ultimate storage in the computer 26. Thus, the sensors 18 can make relative measurements of soil parameters rather than absolute measurements and the manager can analyze this data on the computer 26 to guide turf treatment activities. This reduces the demands on the sensor 18 and allows the use of inexpensive, rugged sensor 18 probes. By placing the sensor 18 functions such as signal processing, analysis, calibration and display on the computer 26, a single computer 26 can handle many sensors 18. Because the electronics and displays are the bulk of the traditional sensor 18 expense an implementation of, for example, 100 sensor nodes 10 using the method of this patent, reduces the expense by approximately a factor of 100.

The electronics necessary to power the sensors 18 and acquire data may be integrated with the node 10 radio 12 electronics. One or more batteries 16 are located in the bottom of the package 22. Preferably, a single circuit board 20 contains the radio 12 and the electronics to power and control the node 10. Preferably, the circuit board 20 includes power management functionality to permit long battery 16 life, for example a minimum of two years, and also includes ability to transmit battery 16 health data to the above ground transceiver 28.

According to one embodiment of the invention, the radio 12 transmits in the unlicensed frequency band (900-928 Mhz), but the principles of the invention are equally applicable to other frequencies. The radio antenna 14 preferably is contained in the top cap of the node 10 so it does not protrude into the soil above the node 10 because that soil may routinely disturbed by plugging/aeration tools.

Referring now to FIGS. 2, 3, data is acquired by the node 10 periodically and transmitted to an above ground transceiver 28 in real-time. In addition, each node 10 is capable of receiving signals from another node 10 and retransmitting them to another node 10 or to a transceiver 28. Circuit board 20 preferably includes memory to temporarily store data collected by sensors 18 and includes an algorithm for selectively activating radio 12 to periodically transmit stored data. Preferably, the data transmitted by each node includes label information to identify the node 10 and sensor 18 that is the source of the data and associating time information with the data so it can be analyzed accurately.

The above ground transceiver 28 uses a radio and electronics package compatible with the node 10. The above ground transceiver 28 preferably is powered by the electricity grid, and is capable of storing data received from the nodes 10. Alternatively, transceiver 28 can be powered by a battery, solar panel or other comparable power source. The data from the above ground transceiver 28 can be transferred to the superintendent's computer 26 in a variety of ways. One is by a wired local area network. Another is by a wireless local area network that can be peer-to-peer radio links or a hybrid mesh network. A third possibility that is practical only if there are few transceivers 28 is a periodic connection of a portable computing device to the above ground transceiver 28 to download the data onto that device which is then carried to the superintendent's computer 26 for transfer.

Data received from transceivers 28 is stored in the superintendent's computer 26 memory device and managed by a standard data base management software such as SQL. The data is analyzed using custom software and displayed in tabular, graphical and “dashboard” formats. The custom software can analyze calibration data and generate calibration factors to be sent to the nodes 10. The custom software can also be used to send commands to control devices 30 (or systems), such as irrigation, fertilization or aeration systems. According to one embodiment of the invention, the superintendent's computer 26 applies an algorithm to generate control commands automatically in response to data collected by the nodes 10. For example, the algorithm on the superintendent's computer 26 can be programmed to automatically activate an irrigation system in the vicinity of a node 10, if the node 10 sends data showing that soil moisture sensed by the node's sensors 18 is below a designated threshold.

In addition, the software analyzes the data received from transceivers 28 to determine if certain undesirable turf conditions exist in the vicinity of one or more nodes 10 or if conditions favorable for promoting such undesirable turf conditions exist in the vicinity of one or more nodes 10. By evaluating the subsurface soil condition data transmitted by nodes 10, the software is programmed to identify, and alert the superintendent of, the presence of conditions favorable to the development of such turf diseases as Pythium Blight, Brown patch, Summer patch, Take All Patch, Dollar Spot, Gray Leaf Spot and Anthracnose. For example, if a node 10 senses high moisture, high temperature and high salinity at a location, it is likely that one or more of the above diseases is present or is likely to develop in the vicinity of that node 10. Furthermore, when one of these turf diseases is identified by physical observation in the vicinity of one or more nodes 10, but was not predicted by the software based on the soil profile, the software can be programmed to use the actual historical conditions monitored by the node(s) 10 and stored in the superintendent's computer 26 as a warning profile for future occurrences of the disease.

Transceivers 28 are placed approximately 4-10 feet above ground and can communicate with nodes 10 within a radius of 200-400 feet depending on terrain. The transceivers 28 are small (˜1×3″×6″) and are placed on trees, poles, irrigation control pedestals and other places in various ways so they are inconspicuous.

An embodiment of the present invention includes nodes 10 that transmit control commands rather than, or in addition to, collecting data from sensors 18. According to this embodiment, control commands from the manager's computer 26 are communicated to the above ground transceivers 28, which transmit the commands to one or more nodes 10. The nodes 10 then communicate the commands to one or more control devices 30 used for turf management, for example an aeration or irrigation system. According to this embodiment, the wires 24 of the node 10 are connected to turf management equipment rather than (or in addition to) sensor 18 probes.

According to the present invention, the method of installing a sensor node 10 comprises the steps of (1) digging a hole where the node 10 is to be emplaced, (2) emplacing the node 10, (3) inserting the node's 10 sensor 18 probes into root zone, and (4) refilling the hole. Preferably, the hole for emplacement of the node 10 is dug using a cup hole cutter tool, which is commonly used on golf courses to form new holes on putting greens. The nodes 10 are sized such that a hole formed by such a tool is sufficient to contain a node 10. Preferably, before refilling the hole, an additional step of checking communication with the node 10 is also performed.

While there has been illustrated and described what is at present considered to be the preferred embodiment of the present invention, it should be understood and appreciated that modifications may be made by those skilled in the art and that the appended claims encompass all such modifications that fall within the full spirit and scope of the present invention.

What is claimed is:

1. A system for monitoring subsurface soil conditions, comprising:
a node, further comprising:
a sensor for sensing data related to at least one subsurface soil condition;
a node transceiver for transmitting and receiving signals that include soil condition data and node commands;
a power source for providing power to the node transceiver;
a processor for receiving and analyzing soil condition data; and
a communications network for providing communications between said node and said processor.

2. The system of claim 1, wherein said node is positioned below ground.

3. The system of claim 2, wherein said node comprises a cylindrical package less than 6 inches in diameter and less than 10 inches in height.

4. The system of claim 1, wherein said cylindrical package is watertight and decay-resistant.

5. The system of claim 1, wherein said node comprises a plurality of sensors 18 for sensing a plurality of subsurface soil conditions.

6. The system of claim 1, wherein said node includes a plurality of sensors 18 for sensing a single subsurface soil condition at a plurality of soil depths.

7. The system of claim 1, wherein said communications network comprises a network transceiver for receiving data signals from said node and transmitting them to said processor and for receiving command signals from said processor and transmitting them to said node.

8. The system of claim 1, wherein said network transceiver is positioned above ground.

9. The system of claim 1, wherein said network transceiver receives data from and transmits data to a plurality of nodes.

10. The system of claim 1, wherein said node further comprises a switch for controlling a turf treatment device.

11. The system of claim 1, wherein said system further comprises a turf treatment device and said processor selectively provides commands to said node to operate said turf treatment device.

12. The system of claim 1, wherein said turf treatment device is selected from the group consisting of aeration pump, air pusher, irrigation sprinkler and fertilizer applicator.

13. The system of claim 1, wherein said at least one subsurface soil condition is selected from the group consisting of pH, salinity, moisture content and temperature.

14. The system of claim 1, wherein said processor includes an algorithm for automatic control of said soil treatment device in response to said soil condition data.

15. The system of claim 1, wherein said processor includes an algorithm for identifying undesirable turf conditions in response to said soil condition data.

16. The system of claim 1, wherein the undesirable turf condition is selected from the group consisting of Pythium Blight, Brown patch, Summer patch, take all patch, Dollar spot, Gray Leaf Spot and Anthracnose.

17. The system of claim 1, wherein said nodes further comprise an algorithm for power management.

18. The system of claim 1, wherein said algorithm controls the report rate of said node.

19. The system of claim 1, wherein said report rate is selectively modifiable in response to operator command.

20. The system of claim 1, wherein each node is associated with a unique identifier.

21. The system of claim 1, wherein said node comprises location means.

22. The system of claim 1, wherein said processor comprises a database that includes location information related to each said node.

23. The system of claim 1, wherein said sensor produces an output that can be calibrated to respond to different soil types.

24. The system of claim 1, wherein said sensor output is calibrated in response to a command from said processor.

25. A node for use with a system for monitoring subsurface soil conditions, comprising:
a sensor for sensing data related to at least one subsurface soil condition;
a node transceiver for transmitting and receiving signals that include soil condition data and node commands;
a power source for providing power to said node transceiver.

26. The node of claim 1, wherein said node comprises a plurality of sensors 18 for sensing a plurality of subsurface soil conditions.

27. The node of claim 1, wherein said node includes a plurality of sensors 18 for sensing a single subsurface soil condition at a plurality of soil depths.

28. The node of claim 1, wherein said node further comprises a switch for controlling a soil treatment device.

29. The node of claim 1, wherein said node controls said soil treatment device in response to a command from a processor.

30. The node of claim 1, wherein said sensor produces an output that can be calibrated to respond to different soil types.

31. The node of claim 1, wherein said sensor output is calibrated in response to a command from a processor.

32. A processor for use with a system for monitoring subsurface soil conditions, comprising:
an input for receiving soil condition data from a communications network;
a database for storing soil condition data and operator commands;
an algorithm for processing soil condition data and operator commands.

33. The processor of claim 1, wherein said algorithm generates a control command and further comprising an output for transmitting said control command to said communications network.

34. The processor of claim 1, wherein said algorithm generates a warning of undesired turf conditions.

35. A method of monitoring subsurface soil conditions and treating related turf conditions comprising the steps of:
providing a node having a sensor to detect a subsurface soil condition;
transmitting data about said subsurface soil condition to a communications network;
receiving said data at a processor; and
applying an algorithm to process said data and produce an output.

36. The method of claim 1, wherein said output includes a warning of an unfavorable turf condition.

37. The method of claim 1, wherein said output includes a control command and further comprising the step of transmitting said control command to said node.
